(19) United States
(12) Patent Application Publication
(10) Pub. No.: US 2025/0311599 A1
(43) Pub. Date: Oct. 2, 2025

(54) DISPLAY DEVICE COMPRISING LENS ARRAY

(71) Applicant: Samsung Display Co., LTD., Yongin-si (KR)

(72) Inventors: Woong Sik KIM, Yongin-si (KR); Rae Young KIM, Yongin-si (KR); Dong Hwan BAE, Yongin-si (KR); Hyeong Gyu KIM, Yongin-si (KR)

(21) Appl. No.: 19/020,890

(22) Filed: Jan. 14, 2025

(30) Foreign Application Priority Data
Mar. 27, 2024 (KR) 10-2024-0041721

(51) Int. Cl. H10K 59/80; H10K 59/122

(52) U.S. Cl. CPC H10K 59/879; H10K 59/122; H10K 59/873

(57) ABSTRACT

A display device includes: a substrate; a pixel circuit layer including circuit elements of each of a plurality of sub-pixels, the pixel circuit layer being on the substrate; a light emitting element layer on the pixel circuit layer, the light emitting element layer including a pixel defining layer defining an opening; an encapsulation layer on the light emitting element layer; and an optical functional layer on the encapsulation layer, the optical function layer including a lens corresponding to each of the plurality of sub-pixels, wherein a first length between a top surface of the lens and a top surface of the encapsulation layer is a sum of a half of a gap length and an emission length, wherein the gap length is a width of the pixel defining layer between openings respectively corresponding to the plurality of sub-pixels, and wherein the emission length is a width of the opening.

### CROSS-REFERENCE TO RELATED APPLICATION

The present application claims priority to and the benefit of Korean patent application No. 10-2024-0041721, filed on Mar. 27, 2024, in the Korean Intellectual Property Office, the entire disclosure of which is incorporated herein by reference.

### BACKGROUND

### 1. Field

Aspects of some embodiments of the present disclosure generally relate to a display device comprising a lens array.

### 2. Description of the Related Art

With the development of information technologies, the importance of display devices which provide a connection medium between users and information has increased. Accordingly, display devices such as liquid crystal display devices and organic light emitting display devices are increasingly used.

In order to implement Augmented Reality (AR), Virtual Reality (VR), and a Mixed Reality (MR), a display device may be utilized, in which an output light amount is increased, so that relatively high luminance can be expressed.

The above information disclosed in this Background section is only for enhancement of understanding of the background and therefore the information discussed in this Background section does not necessarily constitute prior art.

### SUMMARY

Aspects of some embodiments provide a display device in which an output light amount is relatively increased, so that high luminance can be expressed.

According to some embodiments of the present disclosure, a display device includes: a substrate; a pixel circuit layer including circuit elements of each of a plurality of sub-pixels, the pixel circuit layer being on the substrate; a light emitting element layer on the pixel circuit layer, the light emitting element layer including a pixel defining layer defining an opening; an encapsulation layer on the light emitting element layer; and an optical functional layer on the encapsulation layer, the optical function layer including a lens corresponding to each of the plurality of sub-pixels, wherein a first length between a top surface of the lens and a top surface of the encapsulation layer is a sum of a half of a gap length and an emission length, wherein the gap length is a width of the pixel defining layer between openings respectively corresponding to the plurality of sub-pixels, and wherein the emission length is a width of the opening.

According to some embodiments, a second length between a bottom surface of the lens and the top surface of the lens may be smaller than a half of the first length.

According to some embodiments, a third length between the bottom surface of the lens and the top surface of the encapsulation layer may be greater than a half of the first length.

According to some embodiments, the emission length may be a width of the opening along a first direction. The gap length may be a width of the pixel defining layer along the first direction between openings respectively corresponding to the plurality of sub-pixels. The first direction may be a direction in which the plurality of sub-pixels are arranged.

According to some embodiments, a section of the lens may have a trapezoidal shape.

According to some embodiments, a section of the lens may have an isosceles trapezoidal shape.

According to some embodiments, a section of the lens may have a semicircular shape.

According to some embodiments, a section of the lens may have a double tapered shape.

According to some embodiments, a section of the lens may have a hexagonal shape. The hexagonal shape may include first and second angles generated by bending each of a pair of sides which are not parallel to each other in the isosceles trapezoidal shape.

According to some embodiments, a fourth length between a vertex at which two sides forming the first angle meet each other and the bottom surface of the lens may be smaller than the third length.

According to some embodiments, a section of the lens may have a shape in which each of a pair of sides which are not parallel to each other in the isosceles trapezoidal shape is rounded.

According to some embodiments, the optical functional layer may include a color filter layer and a lens array including the lens.

According to some embodiments, the lens array may be on the color filter layer.

According to some embodiments, the display device may include a buffer layer between the lens and the optical functional layer.

According to some embodiments of the present disclosure, a display device includes: an encapsulation layer on a substrate; a color filter layer on the encapsulation layer; and a lens array on the color filter layer, the lens array including a lens corresponding to each of a plurality of sub-pixels, wherein a first length between a top surface of the lens and a top surface of the encapsulation layer is a sum of a half of a gap length and an emission length, wherein the gap length is a width of a pixel defining layer between openings respectively corresponding to the plurality of sub-pixels, and wherein the emission length is a width of the opening.

According to some embodiments, a second length between a bottom surface of the lens and the top surface of the lens may be smaller than a half of the first length.

According to some embodiments, a third length between the bottom surface of the lens and the top surface of the encapsulation layer may be greater than a half of the first length.

According to some embodiments, a section of the lens may have a trapezoidal shape.

According to some embodiments, a section of the lens may have a semicircular shape.

According to some embodiments, a section of the lens may have a hexagonal shape. The hexagonal shape may include first and second angles generated by bending each of a pair of sides which are not parallel to each other in the isosceles trapezoidal shape.

According to some embodiments, a section of the lens may have a shape in which each of a pair of sides which are not parallel to each other in the isosceles trapezoidal shape is rounded.

### BRIEF DESCRIPTION OF THE DRAWINGS

Aspects of some embodiments will now be described more fully hereinafter with reference to the accompanying drawings; however, they may be embodied in different forms and should not be construed as limited to the embodiments set forth herein. Rather, these embodiments are provided so that the present disclosure will be more thorough and more complete, and will more fully convey the scope of embodiments according to the present disclosure to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating aspects of a display device according to some embodiments.

FIG. 2 is a plan view illustrating aspects of a display panel shown in FIG. 1 according to some embodiments.

FIG. 3 is an exploded perspective view illustrating a portion of the display device shown in FIG. 2 according to some embodiments.

FIG. 4 is a plan view illustrating aspects of any one of pixels shown in FIG. 3 according to some embodiments.

FIG. 5 is a sectional view taken along the line I-I′ shown in FIG. 4 according to some embodiments.

FIG. 6 is a view illustrating aspects of a lens area shown in FIG. 5 according to some embodiments.

FIG. 7 is a view illustrating aspects of the lens area shown in FIG. 5 according to some embodiments.

FIG. 8 is a view illustrating aspects of the lens area shown in FIG. 5 according to some embodiments.

FIG. 9 is a view illustrating aspects of the lens area shown in FIG. 5 according to some embodiments.

FIG. 10 is a block diagram illustrating aspects of a display system according to some embodiments.

FIG. 11 is a perspective view illustrating an application example of the display system shown in FIG. 10 according to some embodiments.

FIG. 12 is a view illustrating a head mounted display device shown in FIG. 11, which is worn by a user according to some embodiments.

### DETAILED DESCRIPTION

Hereinafter, aspects of some embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

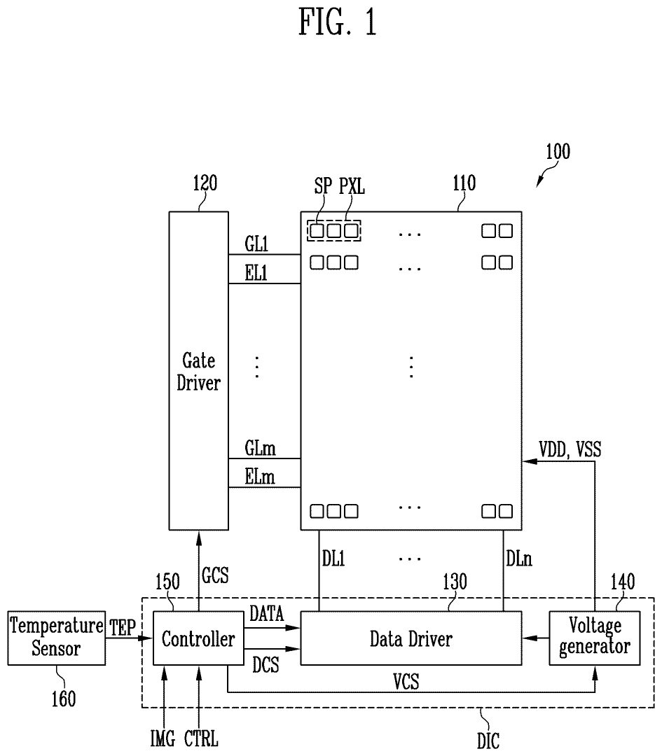

FIG. 1 is a block diagram illustrating aspects of a display device according to some embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. According to some embodiments, the gate control signal GCS may include a start signal indicating a start of each frame, a horizontal synchronization signal for outputting gate signals in synchronization with timings at which data signals are applied, and the like.

According to some embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be located at one side of the display panel 110. However, embodiments according to the present disclosure are not limited thereto. For example, the gate driver 120 may be divided into two or more drivers which are physically and/or logically divided, and these drivers may be located at one side of the display panel 110 and the other side of the display panel 110, which is opposite to the one side. As such, in some embodiments, the gate driver 120 may be arranged in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. According to some embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data line DL1 to DLm. Accordingly, corresponding sub-pixels SP may generate light corresponding to the data signals. Accordingly, an image may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. According to some embodiments, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a reference voltage (e.g., a set or predetermined reference voltage) may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. According to some embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. According to some embodiments, at least one of the data driver 130, the voltage generator 140, or the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. According to some embodiments, the temperature sensor 160 may be arranged to be adjacent to the display panel 110 and/or the driver integrated circuit DIC.

The controller 150 may control various operations of the display device 100 in response to the temperature data TEP. According to some embodiments, the controller 150 may adjust the luminance of an image output from the display panel 100 in response to the temperature data TEP. For example, the controller 150 may control components such as the data driver 130 and/or the voltage generator 140, thereby adjusting data signals and the first and second power voltages VDD and VSS.

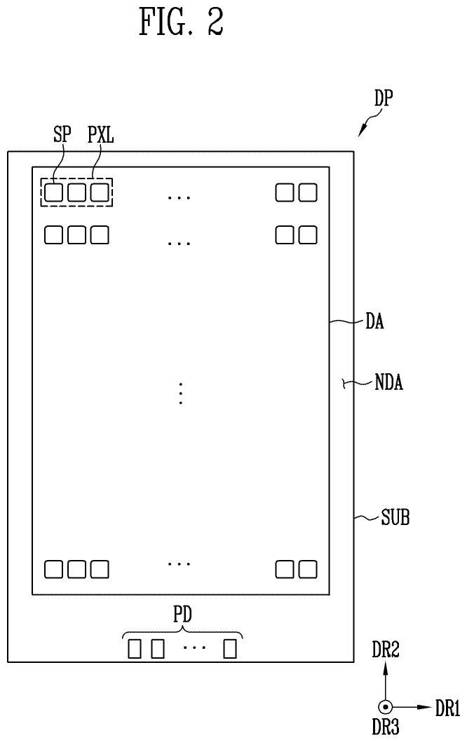

FIG. 2 is a plan view illustrating aspects of a display panel shown in FIG. 1 according to some embodiments.

Referring to FIG. 2, the embodiment DP of the display panel 110 shown in FIG. 1 may include a display area DA and a non-display area NDA. The display panel DP may display images through the display area DA. The non-display area NDA may be located at the periphery (e.g., outside a footprint) of the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. The sub-pixels SP having a relatively high degree of integration may be required. In order to increase the integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDOS) display device.

The sub-pixels SP may be located in the display area DA on the substrate SUB. The sub-pixels SP may be arranged in a matrix form along a first direction DR1 and a second direction DR2 intersecting the first direction DR1. However, embodiments according to the present disclosure are not limited thereto. For example, the sub-pixels SP may be arranged in a zigzag form along the first direction DR1 and the second direction DR2. For example, the sub-pixels SP may be arranged in a PENTILET form or arrangement. The first direction DR1 may be a row direction, and the second direction DR2 may be a column direction.

Two or more sub-pixels among the sub-pixels SP may constitute one pixel PXL.

A component for controlling the sub-pixels SP may be located in the non-display area NDA on the substrate SUB. For example, lines connected to the sub-pixels SP, such as the first to mth gate lines GL1 to GLm and the first to nth data lines DL1 to DLn, which are shown in FIG. 1, may be located in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. According to some embodiments, the gate driver 120 shown in FIG. 1 is mounted on the display panel DP, and may be located in the non-display area NDA. According to some embodiments, the gate driver 120 may be implemented as an integrated circuit distinguished from the display panel DP. According to some embodiments, the temperature sensor 160 may be located in the non-display area NDA to sense a temperature of the display panel DP.

The pads PD may be located in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). According to some embodiments, voltages and signals, which are necessary for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

According to some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

According to some embodiments, the display area DA may have various shapes. The display area DA may have closed-loop shapes including linear sides and/or curved sides. For example, the display area DA may have shapes such as a polygon, a circle, a semicircle, and an ellipse.

According to some embodiments, the display panel DP may have a flat display surface. According to some embodiments, the display panel DP may at least partially have a round display surface. According to some embodiments, the display panel DP may be bendable, foldable or rollable. The display panel DP and/or the substrate SUB may include materials having flexibility.

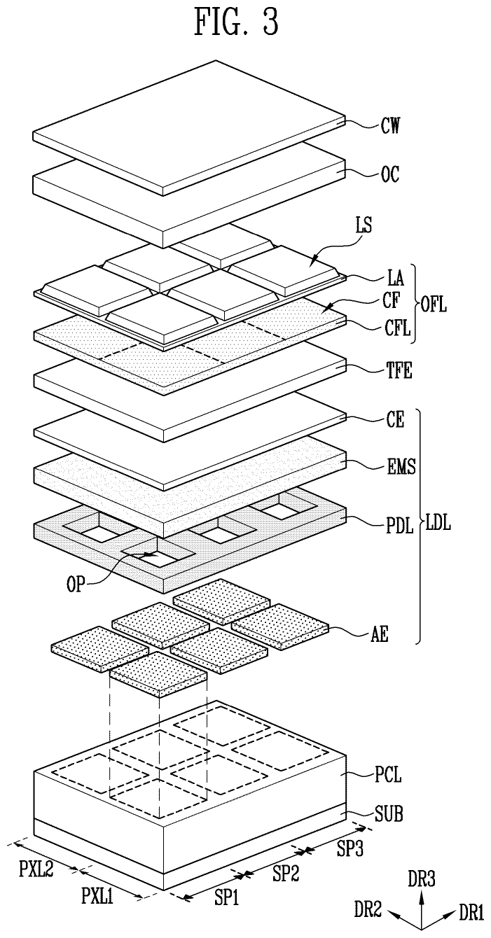

FIG. 3 is an exploded perspective view illustrating a portion of the display device shown in FIG. 2. In FIG. 3, for clear and brief description, a portion of the display panel DP, which corresponds to two pixels PXL1 and PXL2 among the pixels PXL shown in FIG. 2, may be schematically illustrated. A portion of the display panel DP, which corresponds to the other pixels, may also be configured identically.

Referring to FIGS. 2 and 3, each of first and second pixels PXL1 and PXL2 may include first to third sub-pixels SP1 to SP3. However, embodiments according to the present disclosure are limited thereto. For example, each of the first and second pixels PXL1 and PXL2 may include four sub-pixels or include two sub-pixels.

In FIG. 3, it may be illustrated that the first to third sub-pixels SP1 to SP3 may have quadrangular shapes when viewed in a third direction DR3 intersecting the first and second directions DR1 and DR2 (e.g., in a plan view), and have the same size. However, embodiments according to the present disclosure are not limited thereto. The first to third sub-pixels SP1 to SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. According to some embodiments, the substrate SUB may include a glass substrate. According to some embodiments, the substrate SUB may include a polyimide (PI) substrate.

The pixel circuit layer PCL may be located on the substrate SUB. The substrate SUB and/or the pixel circuit layer PCL may include insulating layers and conductive patterns located between the insulating layers. The conductive patterns of the pixel circuit layer PCL may serve as at least some of circuit elements, lines, and the like. The conductive patterns may include copper, but embodiments according to the present disclosure are not limited thereto.

The circuit elements may include a sub-pixel circuit of each of the first to third sub-pixels SP1, SP2, and SP3. The sub-pixel circuit may include transistors and one or more capacitors. Each transistor may include a semiconductor portion including a source region, a drain region, and a channel region, and a gate electrode overlapping with the semiconductor portion. According to some embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. According to some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, the capacitor may include electrodes spaced apart from each other in the third direction DR3 with an insulating layer interposed therebetween.

The lines of the pixel circuit layer PCL may include signal lines, e.g., a gate line, an emission control line, a data line, and the like, which are connected to each of the first to third sub-pixels SP1, SP2, and SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE.

The anode electrodes AE may be located on the pixel circuit layer PCL. The anode electrodes AE may be in contact with the circuit elements of the pixel circuit layer PCL. The anode electrodes AE may include an opaque conductive material capable of reflecting light, but embodiments according to the present disclosure are not limited thereto.

The pixel defining layer PDL may be located on the anode electrodes AE. The pixel defining layer PDL may include an opening OP exposing a portion of each of the anode electrodes AE.

According to some embodiments, the pixel defining layer PDL may include an inorganic material. The pixel defining layer PDL may include a plurality of stacked inorganic layers. For example, the pixel defining layer PDL may include silicon oxide (SiOₓ) and silicon nitride (SiNₓ). According to some embodiments, the pixel defining layer PDL may include an organic material. However, the material of the pixel defining layer PDL is not limited thereto.

The light emitting structure EMS may be located on the anode electrodes AE exposed by the openings OP of the pixel defining layer PDL. The light emitting structure EMS may include a light emitting layer configured to generate light, an electron transport layer configured to transport electrons, a hole transport layer configured to transport holes, and the like.

According to some embodiments, the light emitting structure EMS fills the opening OP of the pixel defining layer PDL, and may be entirely arranged on the top of the pixel defining layer PDL. In other words, the light emitting structure EMS may extend throughout the first to third sub-pixels SP1 to SP3. At least some of the layers in the light emitting structure EMS may be cut or curved at boundaries between the first to third sub-pixels SP1 to SP3. However, embodiments according to the present disclosure are not limited thereto. For example, portions of the light emitting structure EMS, which correspond to the first to third sub-pixels SP1 to SP3, may be separated from each other, and each of the portions may be located in the opening OP of the pixel defining layer PDL.

The cathode electrode CE may be located on the light emitting structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the cathode electrode CE may include at least one of silver (Ag), magnesium (Mg), and/or mixtures thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute one light emitting element. In other words, each of light emitting elements of the first to third sub-pixels SP1 to SP3 may include one anode electrode AE, a portion of the light emitting structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be arranged over the cathode electrode CE. The encapsulation layer TFE may cover the light emitting element layer LDL and/or the pixel circuit layer PCL. The encapsulation layer TFE may be configured to prevent or reduce instances of contaminants such as oxygen and/or moisture infiltrating into the light emitting element layer LDL. According to some embodiments, the encapsulation layer TFE may include a structure in which at least one inorganic layer and at least one organic layer are alternately stacked. For example, the inorganic layer may include silicon nitride, silicon oxide, silicon oxynitride (SiOxNy), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to relatively improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments according to the present disclosure are not limited thereto. The encapsulation layer TFE may further include a thin film formed of at least one of various materials suitable for the improvement of the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured filter light emitted from the light emitting structure EMS, thereby selectively outputting light of a wavelength band or a color, which corresponds to each sub-pixel. The color filter layer CFL may include color filters CF respectively corresponding to the first to third sub-pixels SP1 to SP3. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel, at least some of the color filters CF may be omitted.

The lens array LA may be located on the color filter layer CFL. The lens array LA may include lenses LS respectively corresponding to the first to third sub-pixels SP1 to SP3. Each of the lenses LS may output light emitted from the light emitting structure EMS along an intended path, thereby relatively improving light emission efficiency. The lens array LA may have a relatively high refractive index. For example, the lens array LA may have a refractive index higher than a refractive index of the overcoat layer OC. According to some embodiments, the lenses LS may include an organic material. According to some embodiments, the lenses LS may include an acryl-based material. However, the material of the lenses LS is not limited thereto.

According to some embodiments, as compared with the opening OP of the pixel defining layer PDL, at least some of the color filters CF of the color filter layer CFL and at least some of the lenses LS of the lens array LS may be shifted in a direction parallel to a plane defined by the first and second directions DR1 and DR2. For example, in a central area of the display area DA, the center of a color filter and the center of a lens may be aligned or overlap with the center of a corresponding opening OP of the pixel defining layer PDL. For example, in the central area of the display area DA, the opening OP of the pixel defining layer PDL may completely overlap with the corresponding color filter of the color filter layer CFL and the corresponding lens of the lens array LA. In an area of the display area DA, which is adjacent to the non-display area NDA, the center of a color filter and the center of a lens may be shifted in a planar direction from the center of an opening OP of the pixel defining layer PDL. For example, in the area of the display area DA, which is adjacent to the non-display area NDA, the opening OP of the pixel defining layer PDL may partially overlap with the corresponding color filter of the color filter layer CFL and the corresponding lens of the lens array LA. Accordingly, in the center of the display area DA, light emitted from the light emitting structure EMS can be effectively output in a normal direction of the display surface. At an outer portion of the display area DA, light emitted from the light emitting structure EMS can be effectively output in a direction inclined by an angle (e.g., a set or predetermined angle) with respect to the normal direction of the display surface.

The overcoat layer OC may be arranged over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer or an organic insulating layer. For example, the overcoat layer OC may include epoxy, but embodiments according to the present disclosure are not limited thereto. The overcoat layer OC may have a refractive index lower than a refractive index of the lens array LA.

The cover window CW may be located on the overcoat layer OC. The cover window CW may be configured to protect lower layers thereof. The cover window CW may have a refractive index higher than the refractive index of the overcoat layer OC. The cover window CW may include glass, but embodiments according to the present disclosure are not limited thereto. For example, the cover window CW may be an encapsulation glass configured to protect components located thereunder. According to some embodiments, the cover window CW may be omitted.

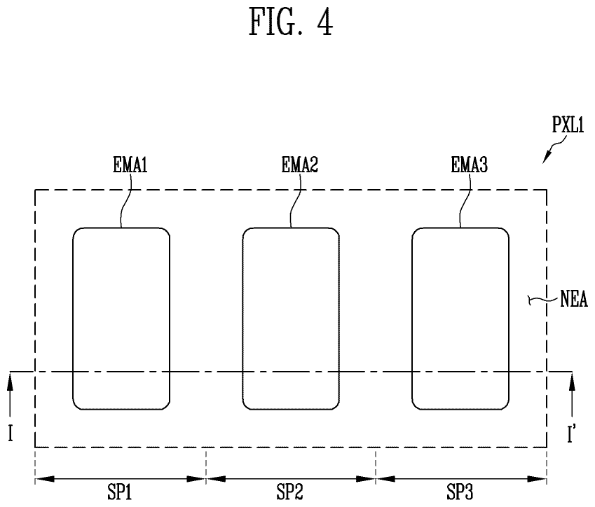

FIG. 4 is a plan view illustrating aspects of any one of the pixels shown in FIG. 3 according to some embodiments. In FIG. 4, for clear and brief description, the first pixel PXL1 among the first and second pixels PXL1 and PXL2 shown in FIG. 3 may be schematically illustrated. The other pixels may be configured identically to the first pixel PXL1.

Referring to FIGS. 3 and 4, the first pixel PXL1 may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of the light emitting structure EMS (see FIG. 3), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3. As described with reference with FIG. 3, each emission area may be understood as an opening OP of the pixel defining layer PDL, which corresponds to each of the first to third sub-pixels SP1 to SP3.

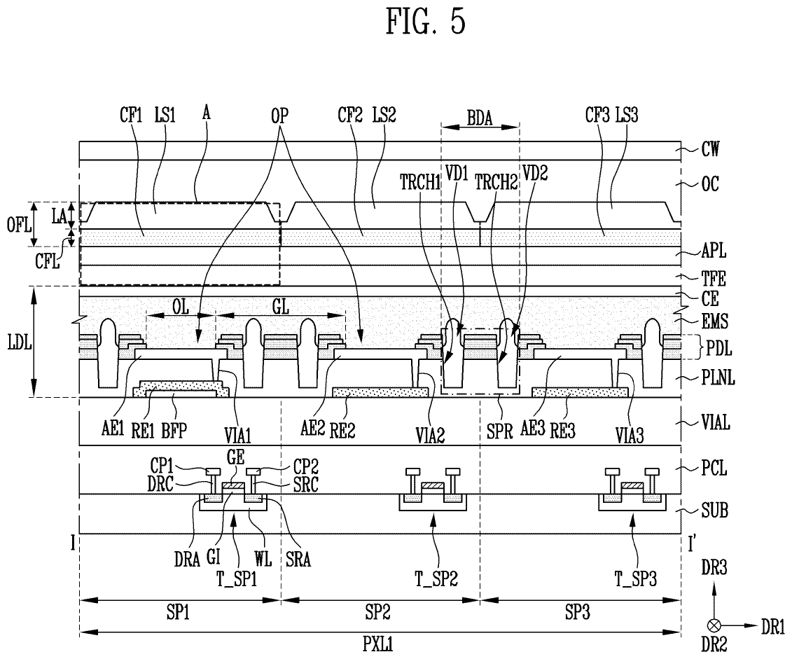

FIG. 5 is a sectional view taken along line I-I′ shown in FIG. 4.

Referring to FIG. 5, a substrate SUB and a pixel circuit layer PCL located on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be located on the substrate SUB. The substrate SUB and the pixel circuit layer PCL may include circuit elements of each of first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit of the first sub-pixel SP1, the transistor T_SP2 of the second sub-pixel SP2 may be any one of transistors included in a sub-pixel circuit of the second sub-pixel SP2, and the transistor T_SP3 of the third sub-pixel SP3 may be any one of transistors included in a sub-pixel circuit of the third sub-pixel SP3. In FIG. 5, for clear and brief description, one of the transistors of each sub-pixel is illustrated, and the other circuit elements are omitted.

The transistors T_SP1 of the first sub-pixel SP1 may include a source region SRA, a drain region DRA, and a gate electrode GE.

The source region SRA and the drain region DRA may be located in the substrate SUB. A well WL formed through an ion implantation process may be located in the substrate SUB, and the source region SRA and the drain region DRA may be located in the well WL to be spaced apart from each other. A region between the source region SRA and the drain region DRA in the well WL may be defined as a channel region.

The gate electrode GE may overlap with the channel region between the source region SRA and the drain region DRA, and be located in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns located between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second conductive patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically to the transistor T_SP1 of the first sub-pixel SP1.

As such, the substrate SUB and the pixel circuit layer PCL may include the circuit elements of each of the first to third sub-pixels SP1 to SP3.

A via layer VIAL may be located on the pixel circuit layer PCL. The via layer VIAL covers the pixel circuit layer PCL, and may have an entirely flat surface. The via layer VIAL may be configured to planarize step differences on the pixel circuit layer PCL. The via layer VIAL may include at least one of silicon oxide (SiOₓ), silicon nitride (SiNₓ), or silicon carbon nitride (SiCN), but embodiments according to the present disclosure are not limited thereto.

A light emitting element layer LDL may be located on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 may be located in the first to third sub-pixels SP1 to SP3, respectively. Each of the first to third reflective electrodes RE1 to RE3 may be in contact with a circuit element located in the pixel circuit layer PCL through a via penetrating the via layer VIAL.

The first to third reflective electrodes RE1 to RE3 may serve as full mirrors which reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or alloys of two or more materials selected therefrom, but embodiments according to the present disclosure are not limited thereto.

According to some embodiments, a connection electrode may be located on the bottom of each of the first to third reflective electrodes RE1 to RE3. The connection electrode may relatively improve an electrical connection characteristic between a corresponding reflective electrode and a circuit element of the pixel circuit layer PCL. The connection electrode may have a multi-layer structure. The multi-layer structure may include titanium (Ti), titanium nitride (TiN), tantalum nitride (TaN), and the like, but embodiments according to the present disclosure are not limited thereto. According to some embodiments, a corresponding reflective electrode may be located between multiple layers of the connection electrode.

A buffer pattern BFP may be located on the bottom of at least one of the first to third reflective electrodes RE1 to RE3A. The buffer pattern BFP may include an inorganic material such as silicon carbon nitride, but embodiments according to the present disclosure are not limited thereto. As the buffer pattern BFP is located, a height of the corresponding reflective electrode in the third direction DR3 may be controlled. For example, the buffer pattern BFP may be located between the first reflective electrode RE1 and the via layer VIAL, to control a height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 can effectively and efficiently output light of the corresponding wavelength range.

In FIG. 5, it is illustrated the buffer pattern BFP is provided to the first sub-pixel SP1 and is not provided to the second and third sub-pixels SP2 and SP3. However, embodiments according to the present disclosure are not limited thereto. The buffer pattern may be provided even in at least one of the second or third sub-pixels SP2 or SP3, to adjust a resonance distance of the at least one of the second or third sub-pixels SP2 or SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be located on the via layer VIAL and the first to third reflective electrodes RE1 to RE3 to planarize step differences between the first to third reflective electrodes RE1 to RE3. The planarization layer PLNL entirely covers the first to third reflective electrodes RE1 to RE3 and the via layer VIAL, and may have a flat surface. According to some embodiments, the planarization layer PLNL may be omitted.

The first to third anode electrodes AE1 to AE3 respectively overlapping with the first to third reflective electrodes RE1 to RE3 may be located on the planarization layer PLNL. The first to third anode electrodes AE1 to AE3 may have shapes similar to the first to third emission areas EMA1 to EMA3 shown in FIG. 4 when viewed in the third direction DR3. The first to third anode electrodes AE1 to AE3 may be electrically connected to the first to third reflective electrodes RE1 to RE3, respectively. The first anode electrode AE1 may be electrically connected to the first reflective electrode RE1 through a first via VIA1 penetrating the planarization layer PLNL. The second anode electrode AE2 may be electrically connected to the second reflective electrode RE2 through a second via VIA2 penetrating the planarization layer PLNL. The third anode electrode AE3 may be electrically connected to the third reflective electrode RE3 through a third via VIA3 penetrating the planarization layer PLNL.

According to some embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO), but embodiments according to the present disclosure are not limited thereto. However, the material of the first to third anode electrodes AE1 to AE3 is not limited thereto. For example, the first to third anode electrodes AE1 to AE3 may include titanium nitride.

According to some embodiments, insulating layers for adjusting a height of at least one of the first to third anode electrodes AE1 to AE3 may be further included. The insulating layers may be located between at least one of the first to third anode electrodes AE1 to AE3 and corresponding reflective electrodes. The planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL may be located on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define an emission area of each of the first to third sub-pixels SP1 to SP3. As such, the pixel defining layer PDL may define the first to third emission areas EMA1 to EMA3 shown in FIG. 4 while being located in the non-emission area NEA shown in FIG. 4.

A width of the opening OP1 along the first direction Dr1 may be designated as an emission length OL. A width of the pixel defining layer PDL along the first direction DR1 between openings OP corresponding to respective sub-pixels may be designated as a gap length GL. Referring to FIG. 5, a gap length GL between an opening OP of the first sub-pixel SP1 and an opening OP of the second sub-pixel SP2 is illustrated.

According to some embodiments, the pixel defining layer PDL may include a plurality of inorganic insulating layers. Each of the plurality of inorganic insulating layers may include at least one of silicon oxide (SiOₓ) or silicon nitride (SiNₓ). For example, the pixel defining layer PDL may include first to third inorganic insulating layers, which are sequentially stacked, the first to third inorganic insulating layers may include silicon nitride, silicon oxide, and silicon nitride, respectively. However, embodiments according to the present disclosure are not limited thereto. The first to third inorganic insulating layers may have a stepped section in an area adjacent to the opening OP.

A separator SPR may be provided in a boundary area BDA between sub-pixels adjacent to each other. In other words, the separator SPR may be provided in each of boundary areas between the sub-pixels SP shown in FIG. 2.

The separator SPR may cause a discontinuity to be formed in the light emitting structure EMS in the boundary area BDA. For example, the light emitting structure EMS may be cut or bent by the separator SPR in the boundary area BDA.

The separator SPR may be provided in or on the pixel defining layer PDL. The pixel defining layer PDL may include one or more trenches TRCH1 and TRCH2 as the separator SPR. According to some embodiments, as shown in FIG. 5, the one or more trenches TRCH1 and TRCH2 may penetrate the pixel defining layer PDL, and partially penetrate the planarization layer PLNL. According to some embodiments, the one or more trenches TRCH1 and TRCH2 may penetrate the pixel defining layer PDL and the planarization layer PLNL, and partially penetrate the via layer VIAL. According to some embodiments, the one or more trenches TRCH1 and TRCH2 may at least partially penetrate the planarization layer PLNL and/or the via layer VIAL, and at least a portion of the pixel defining layer PDL may be located in the one or more trenches TRCH1 and TRCH2.

In FIG. 5, it is illustrated that two trenches TRCH1 and TRCH2 are provided in the boundary area BDA. However, embodiments according to the present disclosure are not limited thereto. For example, the pixel defining layer PDL may include one trench in the boundary area BDA. Alternatively, the pixel defining layer PDL may include three or more trenches in the boundary area BDA.

Due to the first and second trenches TRCH1 and TRCH2, discontinuities such as a first void VD1 and a second void VD2 may be formed in the light emitting structure EMS in the boundary area BDA. Some of a plurality of layers stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS, included in the first to third sub-pixels SP1 to SP3, may be at least partially separated from each other.

In FIG. 5, it is illustrated that the first and second voids VD1 and VD2 are formed in the light emitting structure EMS in the boundary area BDA. However, this is merely illustrative, and embodiments according to the present disclosure are not limited thereto. For example, a concave-shaped valley may be formed in the light emitting structure EMS in the boundary area BDA. The discontinuities formed in the light emitting structure EMS may be variously changed according to shapes of the first and second trenches TRCH1 and TRCH2.

According to some embodiments, the light emitting structure EMS may be formed through a process such as vacuum deposition or inkjet printing. The same materials as the light emitting structure EMS may be located on bottom surfaces adjacent to the via layer VIAL among the first and second trenches TRCH1 and TRCH2.

The separator SPR may be variously modified such that the light emitting structure EMS can have a discontinuity in the boundary area BDA. According to some embodiments, inorganic insulating patterns additionally stacked on the pixel defining layer PDL without the first and second trenches TRCH1 and TRCH2 may be provided in the boundary area BDA. A width of an inorganic insulating pattern at an uppermost portion among the additionally stacked inorganic insulating patterns may be greater than a width of an inorganic insulating pattern located immediately under the inorganic insulating pattern at the uppermost portion. For example, in the boundary area BDA, first to third inorganic insulating patterns are sequentially stacked from the pixel defining layer PDL, and the third inorganic insulating pattern at the uppermost portion may have a width greater than a width of the second inorganic insulating layer. For example, the pixel defining layer PDL may have a section having a “T” shape or an “I” shape in the boundary area BDA. According to the shape of the pixel defining layer PDL, the plurality of layers included in the light emitting structure EMS may be partially cut or bent in the boundary area BDA.

The light emitting structure EMS may be located on the anode electrodes AE exposed by the openings OP of the pixel defining layer PDL. The light emitting structure EMS may fill the openings OP of the pixel defining layer PDL, and be entirely arranged throughout the first to third sub-pixels SP1 to SP3. As described above, the light emitting structure EMS may be partially cut or bent in the boundary area BDA by the separator SPR. Accordingly, in an operation of the display device 100, the magnitude of current leaked from each of the first to third sub-pixels SP1 to SP3 to a sub-pixel adjacent thereto through the layers included in the light emitting structure EMS may be decreased. Thus, first to third light emitting elements can operate with a relatively high reliability.

The cathode electrode CE may be arranged over the light emitting structure EMS. The cathode electrode CE may be commonly provided in the first to third sub-pixels SP1 to SP3. The cathode electrode CE may serve as a half mirror which allow light emitted from the light emitting structure EMS to be partially transmitted therethrough and to be partially reflected therefrom.

The first anode electrode AE1, a portion of the light emitting structure EMS, which overlaps with the first anode electrode AE1, and a portion of the cathode electrode CE, which overlaps with the first anode electrode AE1, may constitute the first light emitting element.

The second anode electrode AE2, a portion of the light emitting structure EMS, which overlaps with the second anode electrode AE2, and a portion of the cathode electrode CE, which overlaps with the second anode electrode AE2, may constitute the second light emitting element.

The third anode electrode AE3, a portion of the light emitting structure EMS, which overlaps with the third anode electrode AE3, and a portion of the cathode electrode CE, which overlaps with the third anode electrode AE3, may constitute the third light emitting element.

An encapsulation layer TFE may be arranged over the cathode electrode CE. The encapsulation layer TFE may prevent or reduce instances of contaminants such as oxygen and/or moisture infiltrating into the light emitting element layer LDL.

An optical functional layer OFL may be located on the encapsulation layer TFE. According to some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to F3 respectively corresponding to the first to third sub-pixels SP1 to SP3. The first to third color filters CF1 to F3 may allow lights having different wavelength ranges to pass therethrough. For example, the first to third color filters CF1 to CF3 may allow light red, green, and blue colors to pass therethrough, respectively.

According to some embodiments, the first to third color filters CF1 to CF3 may partially overlap with each other in the boundary area BDA. According to some embodiments, the first to third color filters CF1 to CF3 may be spaced apart from each other, and a black matrix may be provided between the first to third color filters CF1 to CF3.

The lens array LA may be located on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting layers along intended paths, thereby relatively improving light emission efficiency.

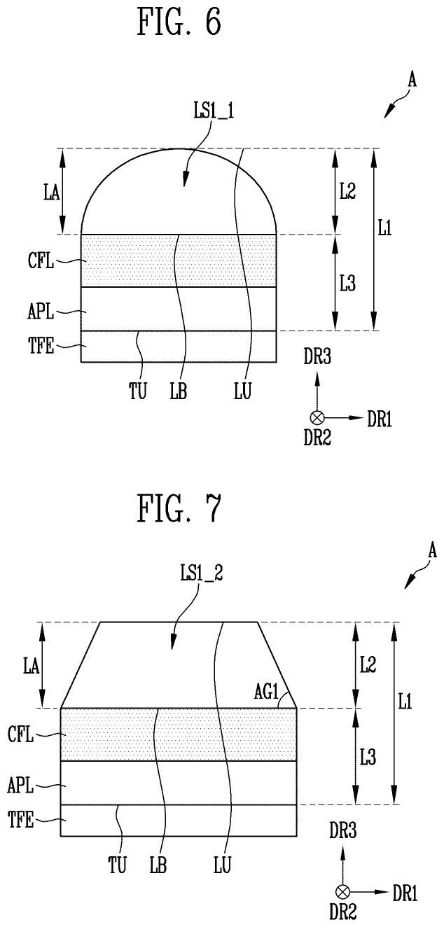

FIG. 6 is a view illustrating aspects of a lens area shown in FIG. 5 according to some embodiments.

Referring to FIGS. 5 and 6, a sectional view of a first lens LS1_1 included in a lens area A is illustrated. An encapsulation layer TFE, an adhesive layer APL, a color filter layer CFL, and a lens array LA, which are shown in FIG. 6, are similar to the encapsulation layer TFE, the adhesive layer APL, the color filter layer CFL, and the lens array LA, which are shown in FIG. 5, and therefore, overlapping descriptions will be omitted.

In FIG. 6, for clear and brief description, the first lens LS1_1 of the lens area A is illustrated, but the other lenses may also be configured identically to the first lens LS1_1.

According to some embodiments, the first lens LS1_1 may have a semicircular shape. As the first lens LS1_1 has the semicircular shape, the color uniformity of the display panel can be relatively improved.

A length between a top surface LU of the first lens LS1_1 and a top surface TU of the encapsulation layer TFE may be designated as a first length L1. The top surface LU of the first lens LS1_1 may be a tangent line of the first lens LS1_1 parallel to the encapsulation layer TFE among tangent lines of the first lens LS1_1.

$$L 1 = OL + \frac{GL}{2} \qquad Equation 1$$

Referring to Equation 1, the first length L1 may be a sum of the emission length OL and a half of the gap length GL.

A length between a bottom surface LB of the first lens LS1_1 and the top surface LU of the first lens LS1_1 may be designated as a second length L2. The second length L2 may be smaller than a half of the first length L1.

A length between the bottom surface LB of the first lens LS1_1 and the top surface TU of the encapsulation layer TFE may be designated as a third length L3. The third length L3 may be greater than a half of the first length L1.

In FIG. 6, it is illustrated that the first lens LS1_1 is located immediately on the color filter layer CFL. However, the present disclosure is not limited thereto, and a buffer layer may be located between the first lens LS1_1 and the color filter layer CFL.

According to some embodiments, the buffer layer may be located between the lens array LA and color filter layer CFL. That is, the buffer layer may be located on the color filter layer CFL, and the lens array LA may be located on the buffer layer. Also, the buffer layer may include the same organic material as the first lens LS1_1.

FIG. 7 is a view illustrating aspects of the lens area shown in FIG. 5 according to some embodiments.

Referring to FIGS. 5 and 7, a sectional view of a first lens LS1_2 included in

the lens area A shown in FIG. 5. An encapsulation layer TFE, an adhesive layer APL, a color filter layer CFL, and a lens array LA, which are shown in FIG. 7, are similar to the encapsulation layer TFE, the adhesive layer APL, the color filter layer CFL, and the lens array LA, which are shown in FIG. 5, and therefore, overlapping descriptions will be omitted.

In FIG. 7, for clear and brief description, the first lens LS1_2 of the lens area A is illustrated, but the other lenses may also be configured identically to the first lens LS1_2.

According to some embodiments, the first lens LS1_2 may have a trapezoidal shape. For example, the first lens LS1_2 may have an isosceles trapezoidal shape. A length between a top surface LU of the first lens LS1_2 and a top surface TU of the encapsulation layer TFE may be designated as a first length L1. Like Equation 1 described in FIG. 6, referring to Equation 1, the first length L1 may be a sum of the emission length OL and a half of the gap length GL.

A length between a bottom surface LB of the first lens LS1_2 and the top surface of the first lens LS1_2 may be designated as a second length L2. The second length L2 may be smaller than a half of the first length L1.

A length between the bottom surface LB of the first lens LS1_2 and the top surface TU of the encapsulation layer TFE may be designated as a third length L3. The third length L3 may be greater than a half of the first length L1. According to some embodiments, a first angle AG1 located on the bottom LB of the first lens LS1_2 may be an angle between 50 degrees and 70 degrees.

In FIG. 7, it is illustrated that the second lens LS1_2 is located immediately on the color filter layer CFL. However, the present disclosure is not limited thereto, and a buffer layer may be located between the first lens LS1_2 and the color filter layer CFL.

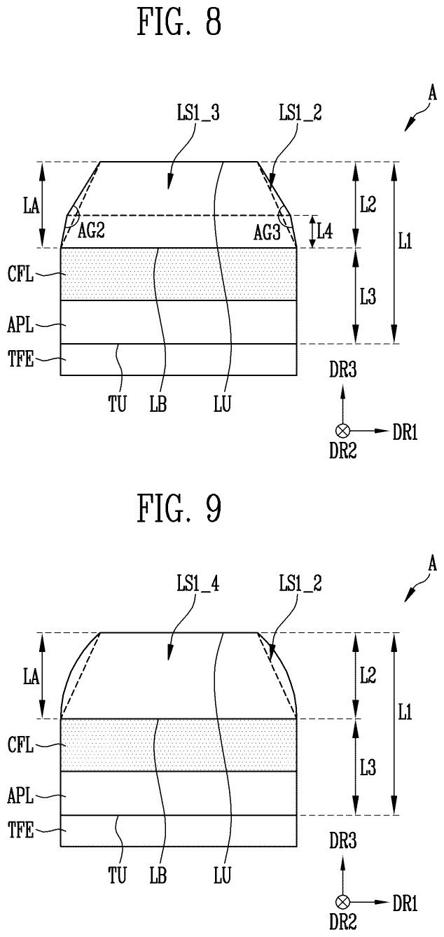

FIG. 8 is a view illustrating aspects of the lens area shown in FIG. 5 according to some embodiments.

Referring to FIGS. 5 and 8, a sectional view of a first lens LS1_3 included in the lens area A shown in FIG. 5. An encapsulation layer TFE, an adhesive layer APL, a color filter layer CFL, and a lens array LA, which are shown in FIG. 8, are similar to the encapsulation layer TFE, the adhesive layer APL, the color filter layer CFL, and the lens array LA, which are shown in FIG. 5, and therefore, overlapping descriptions will be omitted.

In FIG. 8, for clear and brief description, the first lens LS1_3 of the lens area A is illustrated, but the other lenses may also be configured identically to the first lens LS1_3.

According to some embodiments, the first lens LS1_3 may have a hexagonal shape. For example, the first lens LS1_3 shown in FIG. 8 may include second and third angles AG2 and AG3 generated by bending each of a pair of sides which are not parallel to each other in the isosceles trapezoidal shape of the first lens LS1_2 shown in FIG. 7. As the first lens LS1_3 has a double tapered shape, the light emission efficiency of the first lens LS1_3 can be relatively improved.

Each of a vertex at which two sides forming the second angle AG2 meet each other and a vertex at which two sides forming the third angle AG3 meet each other may be located at a point distant by a fourth length L4 from a bottom surface LB of the first lens LS1_3. The fourth length L4 may be smaller than a second length L2. The fourth length L4 may be freely set within a range smaller than the second length L2.

A length between a top surface LU of the first lens LS1_3 and a top surface TU of the encapsulation layer TFE may be designated as a first length L1. Like Equation 1 described in FIG. 1, referring to Equation 1, the first length L1 may be a sum of the emission length OL and a half of the gap length GL.

A length between the bottom surface LB of the first lens LS1_3 and the top surface LU of the first lens LS1_3 may be designated as the second length L2. The second length L2 may be smaller than a half of the first length L1.

A length between the top surface LB of the first lens LS1_3 and the top surface TU of the encapsulation layer TFE may be designated as a third length L3. The third length L3 may be greater than a half of the first length L1.

In FIG. 8, it is illustrated that the first lens LS_3 is located immediately on the color filter layer CFL. However, the present disclosure is not limited thereto, and a buffer layer may be located between the first lens LS1_3 and the color filter layer CFL.

FIG. 9 is a view illustrating aspects of the lens area shown in FIG. 5 according to some embodiments.

Referring to FIGS. 5 and 9, a sectional view of a first lens LS1_4 included in the lens area A shown in FIG. 5. An encapsulation layer TFE, an adhesive layer APL, a color filter layer CFL, and a lens array LA, which are shown in FIG. 9, are similar to the encapsulation layer TFE, the adhesive layer APL, the color filter layer CFL, and the lens array LA, which are shown in FIG. 5, and therefore, overlapping descriptions will be omitted.

In FIG. 9, for clear and brief description, the first lens LS1_4 of the lens area A is illustrated, but the other lenses may also be configured identically to the first lens LS1_4.

According to some embodiments, the first lens LS1_4 may have a rounded quadrangular shape. For example, the first lens LS1_4 shown in FIG. 9 may have a shape in which each of a pair of sides which are not in parallel to each other in the isosceles trapezoidal shape of the first lens LS1_2 shown in FIG. 7 is rounded.

As the first lens LS1_4 has the rounded quadrangular shape, the light emission efficiency of the first lens LS1_4 can be relatively improved.

A length between a top surface LU of the first lens LS1_4 and a top surface TU of the encapsulation layer TFE may be designated as a first length L1. Like Equation 1 described in FIG. 6, referring to Equation 1, the first length L1 may be a sum of the emission length OL and a half of the gap length GL.

A length between a bottom surface LB of the first lens LS1_4 and the top surface LU of the first lens LS1_4 may be designated as a second length L2. The second length L2 may be smaller than a half of the first length L1.

A length between the bottom surface LB of the first lens LS1_4 and the top surface TU of the encapsulation layer TFE may be designated as a third length L3. The third length L3 may be greater than a half of the first length L1.

In FIG. 9, it is illustrated that the first lens LS1_4 is located immediately on the color filter layer CFL. However, the present disclosure is not limited thereto, and a buffer layer may be located between the first lens LS1_4 and the color filter layer CFL.

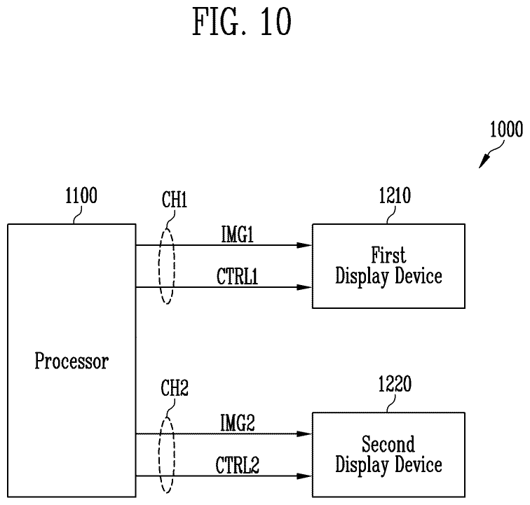

FIG. 10 is a block diagram illustrating aspects of a display system according to some embodiments.

Referring to FIG. 10, a display system 1000 may include a processor 1100 and one or more display devices 1210 and 1220.

The processor 1100 may perform various tasks and various calculations. According to some embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 10, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1. The first image data IMG1 and the first control signal CTRL1 may be provided as the input image data IMG and the control signal CTRL, which are shown in FIG. 1, respectively.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be provided as the input image data IMG and the control signal CTRL, which are shown in FIG. 1, respectively.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, or an augmented reality (AR) device.

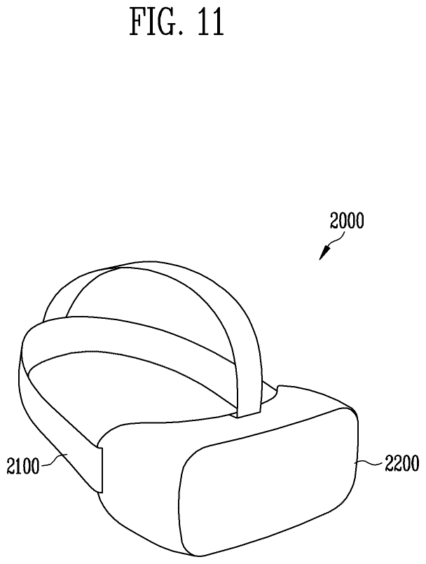

FIG. 11 is a perspective view illustrating an application example of the display system shown in FIG. 10.

Referring to FIG. 11, the display system 1000 shown in FIG. 10 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments according to the present disclosure are not limited thereto. For example, the head mounting band 2100 may be implemented in the form of a glasses frame, a helmet or the like.

The display device accommodating case 2200 may accommodate the first and second display devices 1210 and 1220 shown in FIG. 10. The display device accommodating case 2200 may further accommodate the processor 1100 shown in FIG. 10.

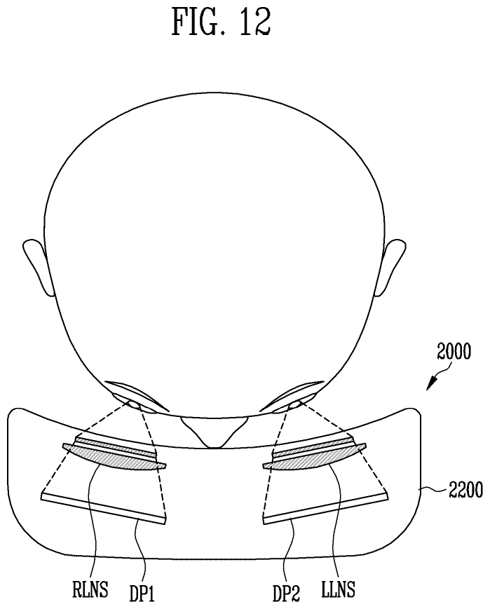

FIG. 12 is a view illustrating a head mounted display device shown in FIG. 11, which is worn by a user.

Referring to FIG. 12, a first display panel DP1 of the first display device 1210 and a second display panel DP2 of the second display device 1220 may be located in the head mounted display device 2000. The head mounted display device 2000 may further include one or more lenses LLNS and RLNS.

In the display device accommodating case 2200, a right-eye lens RLNS may be located between the first display panel DP1 and a right eye of the user. In the display device accommodating case 2200, a left-eye lens LLNS may be located between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

According to some embodiments, each of the right-eye lens RLNS and the left-eye lens LLNS may include an optical lens having a pancake-shaped section. According to some embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

In the display device according to some embodiments of the present disclosure, a leakage current through a common layer between adjacent pixels can be prevented or reduced, and damage of adjacent pixels can be prevented or reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, and their equivalents.

What is claimed is:

1. A display device comprising:
a substrate;
a pixel circuit layer including circuit elements of each of a plurality of sub-pixels, the pixel circuit layer being on the substrate;
a light emitting element layer on the pixel circuit layer, the light emitting element layer including a pixel defining layer defining an opening;
an encapsulation layer on the light emitting element layer; and
an optical functional layer on the encapsulation layer, the optical function layer including a lens corresponding to each of the plurality of sub-pixels,
wherein a first length between a top surface of the lens and a top surface of the encapsulation layer is a sum of a half of a gap length and an emission length,
wherein the gap length is a width of the pixel defining layer between openings respectively corresponding to the plurality of sub-pixels, and
wherein the emission length is a width of the opening.

2. The display device of claim 1, wherein a second length between a bottom surface of the lens and the top surface of the lens is smaller than a half of the first length.

3. The display device of claim 2, wherein a third length between the bottom surface of the lens and the top surface of the encapsulation layer is greater than a half of the first length.

4. The display device of claim 3, wherein the emission length is a width of the opening along a first direction,
wherein the gap length is a width of the pixel defining layer along the first direction between openings respectively corresponding to the plurality of sub-pixels, and
wherein the first direction is a direction in which the plurality of sub-pixels are arranged.

5. The display device of claim 3, wherein a section of the lens has a trapezoidal shape.

6. The display device of claim 5, wherein a section of the lens has an isosceles trapezoidal shape.

7. The display device of claim 3, wherein a section of the lens has a semicircular shape.

8. The display device of claim 3, wherein a section of the lens has a double tapered shape.

9. The display device of claim 8, wherein a section of the lens has a hexagonal shape, and
wherein the hexagonal shape includes first and second angles generated by bending each of a pair of sides which are not parallel to each other in an isosceles trapezoidal shape.

10. The display device of claim 9, wherein a fourth length between a vertex at which two sides forming the first angle meet each other and the bottom surface of the lens is smaller than the third length.

11. The display device of claim 3, wherein a section of the lens has a shape in which each of a pair of sides which are not parallel to each other in an isosceles trapezoidal shape is rounded.

12. The display device of claim 3, wherein the optical functional layer includes a color filter layer and a lens array including the lens, and
wherein the lens array is on the color filter layer.

13. The display device of claim 12, further comprising a buffer layer between the lens and the color filter layer.

14. A display device comprising:
an encapsulation layer on a substrate;
a color filter layer on the encapsulation layer; and
a lens array on the color filter layer, the lens array including a lens corresponding to each of a plurality of sub-pixels,
wherein a first length between a top surface of the lens and a top surface of the encapsulation layer is a sum of a half of a gap length and an emission length,
wherein the gap length is a width of a pixel defining layer between openings respectively corresponding to the plurality of sub-pixels, and
wherein the emission length is a width of the opening.

15. The display device of claim 14, wherein a second length between a bottom surface of the lens and the top surface of the lens is smaller than a half of the first length.

16. The display device of claim 15, wherein a third length between the bottom surface of the lens and the top surface of the encapsulation layer is greater than a half of the first length.

17. The display device of claim 16, wherein a section of the lens has a trapezoidal shape.

18. The display device of claim 16, wherein a section of the lens has a semicircular shape.

19. The display device of claim 16, wherein a section of the lens has a hexagonal shape, and
wherein the hexagonal shape includes first and second angles generated by bending each of a pair of sides which are not parallel to each other in an isosceles trapezoidal shape.

20. The display device of claim 16, wherein a section of the lens has a shape in which each of a pair of sides which are not parallel to each other in an isosceles trapezoidal shape is rounded.
